(19) United States
(12) Patent Application Publication
(10) Pub. No.: US 2010/0213828 A1
(43) Pub. Date: Aug. 26, 2010

(54) ORGANIC LIGHT EMITTING DIODE DISPLAY

(75) Inventors: Sang-Joon SEO, Yongin-City (KR); Kie Hyun NAM, Yongin-City (KR); Jung-Woo MOON, Yongin-City (KR)

Correspondence Address: ROBERT E. BUSHNELL & LAW FIRM, 2029 K STREET NW, SUITE 600, WASHINGTON, DC, 20006-1004, US

(73) Assignee: SAMSUNG MOBILE DISPLAY CO., LTD., Yongin-City (KR)

(21) Appl. No.: 12/691,778

(22) Filed: Jan. 22, 2010

(30) Foreign Application Priority Data
Feb. 26, 2009 (KR) 10-2009-0016494

(51) Int. Cl. H01J 1/62; H01J 9/24

(52) U.S. Cl. 313/504; 445/24

(57) ABSTRACT

An OLED display that includes a substrate main body, an OLED formed on the substrate main body, a moisture absorbing layer formed on the substrate main body and covering the OLED, an organic barrier layer formed on the substrate main body and covering the moisture absorbing layer, and an inorganic barrier layer formed on the substrate main body and covering the organic barrier layer.

### CLAIM OF PRIORITY

This application makes reference to, incorporates the same herein, and claims all benefits accruing under 35 U.S.C. §119 from an application earlier filed in the Korean Intellectual Property Office on Feb. 26, 2009 and there duly assigned Serial No. 10-2009-0016494.

### BACKGROUND OF THE INVENTION

1. Field of the Invention

The present invention relates to an organic light emitting diode (OLED) display. More particularly, it relates to a thin film encapsulated OLED display.

2. Description of the Related Art

An OLED display has self-luminance characteristics, and the thickness and weight thereof can be reduced since it does not require a separate light source, unlike a liquid crystal display (LCD). In addition, since the OLED display exhibits high-quality characteristics such as low power consumption, high luminance, high response speed, etc., it is receiving much attention as a next-generation display device.

The OLED display includes a plurality of OLEDs respectively having a hole injection electrode, an organic emission layer, and an electron injection electrode. When the anode and cathode inject holes and electrons into the organic light emitting layer, the OLEDs emit light using energy generated when excitons generated by electron-hole combinations in the organic light emitting layer are dropped from an excited state to a ground state, and an image is displayed when the excitons are dropped from an excited state to a ground state.

However, the organic emission layer is sensitive to external environment factors such as moisture and oxygen so that quality of the OLED display may be deteriorated when being exposed to the moisture or oxygen. Therefore, in order to protect the OLEDs and prevent permeation of the moisture and oxygen into the organic emission layer, an encapsulation substrate is sealed to a display substrate where the OLEDs are formed through an additional sealing process, or a thick protection layer is formed on the OLEDs.

However, when the encapsulation substrate is used or the protection layer is formed, the manufacturing process of the OLED display becomes complicated to perfectly prevent permeation of the moisture or oxygen into the organic emission layer and the entire thickness of the OLED display cannot be formed to be slim.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide an OLED display that can effectively suppress permeation of moisture of oxygen into an organic emission layer through a thin film encapsulation layer, and to simultaneously make the entire thickness slim.

In addition, the present invention provides a manufacturing method of an OLED display that can efficiently form the thin film encapsulation layer.

An OLED display according to an exemplary embodiment of the present invention includes a substrate main body, an OLED formed on the substrate main body, a moisture absorbing layer formed on the substrate main body and covering the OLED, an organic barrier layer formed on the substrate main body and covering the moisture absorbing layer, and an inorganic barrier layer formed on the substrate main body and covering the organic barrier layer.

The moisture absorbing layer may be formed of a material that is made of at least one of silicon monoxide (SiO), calcium monoxide (CaO), and barium monoxide (BaO).

The organic barrier layer may be made of a polymer-based material.

The moisture absorbing layer and the organic barrier layer may be consecutively formed through thermal evaporation processes.

At least one of the thermal evaporation processes may include a vacuum evaporation method.

The entire thickness of the moisture absorbing layer and the organic barrier layer may be included within a range of 1 nm to 1000 nm.

The moisture absorbing layer prevents permeation of moisture generated during the process of forming the organic barrier layer into the organic emission layer.

The inorganic barrier layer may be made of a material that includes at least one of Al₂O₃, TiO₂, ZrO, SiO₂, AlON, AlN, SiON, Si₃N₄, ZnO and Ta₂O₅.

The inorganic barrier layer may be formed through an atomic layer deposition (ALD) method.

The entire thickness of the moisture absorbing layer, the organic barrier layer, and the inorganic barrier layer may be included within a range of 10 nm to 10,000 nm.

A manufacturing method of an OLED display according to another exemplary embodiment of the present invention includes forming an OLED on a substrate main body, forming a moisture absorbing layer that covers the OLED through a thermal evaporation process, forming an organic barrier layer that covers the moisture absorbing layer through the thermal evaporation process, and forming an inorganic barrier layer that covers the organic barrier layer through an atomic layer deposition (ALD) method.

The moisture absorbing layer may be formed of a material including at least one of silicon monoxide (SiO), calcium monoxide (CaO), and barium monoxide (BaO).

The organic barrier layer may be made of a polymer-based material.

At least one of the thermal evaporation processes may include a vacuum evaporation method.

The moisture absorbing layer may be made by deposition of silicon monoxide that is formed from reaction of silicon dioxide (SiO₂) and silicon gas.

The moisture absorbing layer and the organic barrier layer may be consecutively formed through the thermal evaporation processes.

The moisture absorbing layer may prevent permeation of moisture generated during the process for forming the organic barrier layer into an organic emission layer.

The entire thickness of the moisture absorbing layer and the organic barrier layer may be formed to be included within a range of 1 nm to 1000 nm.

The inorganic barrier layer may be made of a material that includes at least one of Al₂O₃, TiO₂, ZrO, SiO₂, AlON, AlN, SiON, Si₃N₄, ZnO and Ta₂O₅.

The entire thickness of the moisture absorbing layer, the organic barrier layer, and the inorganic barrier layer may be formed to be included within a range of 10 nm to 10,000 nm.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view of an OLED display according to an exemplary embodiment of the present invention.

FIG. 2 is a layout view of a pixel circuit of the OLED display of FIG. 1.

FIG. 3 is a partially enlarged cross-sectional view of the OLED display of FIG. 1.

FIG. 4 and FIG. 5 are flowcharts of a manufacturing method of an OLED display according to an exemplary embodiment of the present invention.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In order to describe the present invention more clearly, parts that are not related to the description will be omitted from the drawings, and the same symbols will be given to similar parts throughout the specification.

Furthermore, as the size and thickness of the respective structural components shown in the drawings are arbitrarily illustrated for explanatory convenience, the present invention is not necessarily limited to as illustrated.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

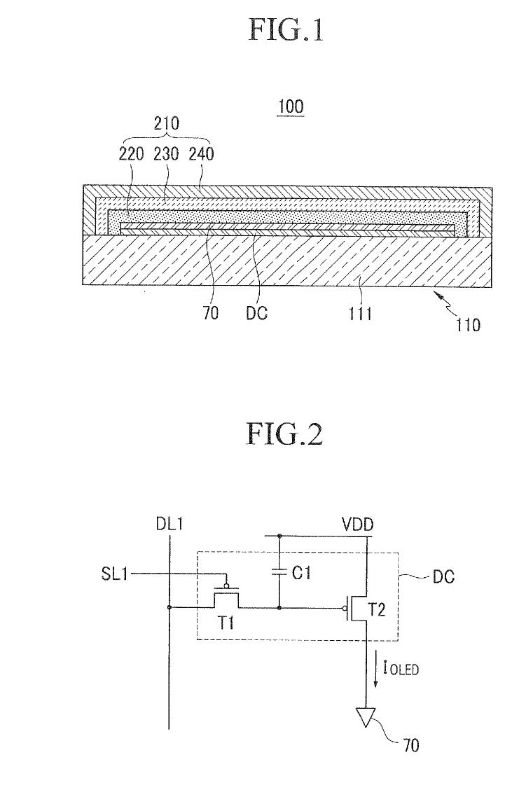

Hereinafter, an exemplary embodiment of the present invention will be described with reference to FIG. 1 to FIG. 3.

As shown in FIG. 1, an organic light emitting diode (OLED) display 100 includes a display substrate 110 and a thin film encapsulation layer 210.

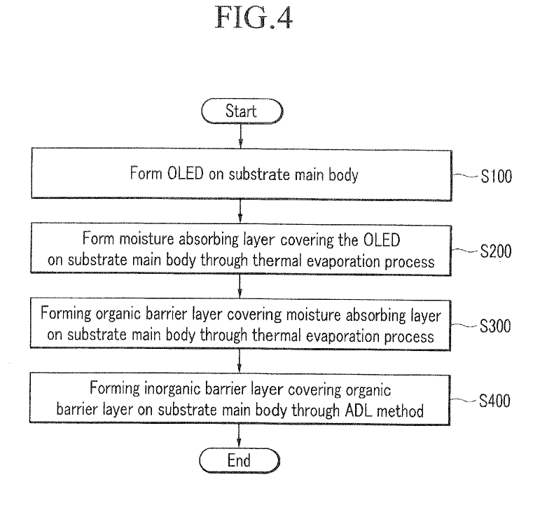

The display substrate 110 includes a substrate main body 111, a driving circuit unit DC, and an OLED 70. The driving circuit unit DC and the OLED 70 are formed on the substrate main body 111. The OLED 70 displays an image with an organic emission layer 720 (shown in FIG. 3) that emits light, and the driving circuit unit DC drives the OLED 70. Structures of the OLED 70 and the driving circuit unit DC are not limited to the structures shown in FIG. 1 to FIG. 3, and they may be variously modified within a range that can be easily realized by a person skilled in the art according to a direction of an image display with light emitted from the OLED 70.

The thin film encapsulation layer 210 includes a moisture absorbing layer 220, an organic barrier layer 230, and an inorganic barrier layer 240 that are sequentially formed on the substrate main body 111.

The moisture absorbing layer 220 covers the OLED for protection. The moisture absorbing layer 220 is formed of one of silicon monoxide (SiO), calcium monoxide (CaO), and barium monoxide (BaO).

In addition, the moisture absorbing layer 220 is formed through a thermal evaporation process such as a vacuum evaporation method. The thermal evaporation process for forming the moisture absorbing layer 220 may be performed within a range of temperature that does not damage the OLED 70. Therefore, damage to the OLED 70 during the process for forming the moisture absorbing layer 220 can be prevented.

The organic barrier layer 230 covers the moisture absorbing layer 220 to secondarily protect the OLED 70. The organic barrier layer 230 is made of a polymer-based material. Here, the polymer-based material includes acryl-based resin, epoxy-based resin, polyimide, and polyethylene.

In addition, the organic barrier layer 230 is formed through the thermal evaporation process. The thermal evaporation process for forming the organic barrier layer 230 may be performed within a range of temperature that does not damage the OLED 70.

In addition, the moisture absorbing layer 220 and the organic barrier layer 230 may be consecutively performed through the thermal evaporation process. Therefore, the entire manufacturing process of the thin film encapsulation layer 210 can be relatively easy and damage to the OLED 70 can be minimized.

The moisture absorbing layer 220 made of the polymer-based material prevents permeation of water generated when the organic barrier layer 230 is formed through the thermal evaporation process into the OLED 70.

In addition, the entire thickness of the moisture absorbing layer 220 and the organic barrier layer 230 consecutively formed through the thermal evaporation process is included within a range of 1 nm to 1000 nm. When the entire thickness of the moisture absorbing layer 220 and the organic barrier layer 230 is less than 1 nm, it is difficult to stably protect the OLED 70 and prevent permeation of moisture or oxygen. When the entire thickness of the moisture absorbing layer 220 and the organic barrier layer 230 is greater than 1000 nm the entire thickness of the OLED display 100 is increased more than necessary. Thus, it is preferred that the entire thickness of the moisture absorbing layer 220 and the organic barrier layer 230 is included within a range of 300 nm to 500 nm.

The inorganic barrier layer 240 covers the organic barrier layer 230 to thirdly protect the OLED 70. The inorganic barrier layer 240 is formed of a material that includes at least one of inorganic insulation materials such as Al₂O₃, TiO₂, ZrO, SiO₂, AlON, AlN, SiON, Si₃N₄, ZnO, and Ta₂O₅.

In addition, the inorganic barrier layer 240 is formed through an atomic layer deposition (ALD) method. According to the ADL method, the inorganic barrier layer 240 may be formed by growing the above-enumerated inorganic materials at a temperature below 100 degrees Celsius in order to not damage the OLED 70. The inorganic barrier layer 240 has high density so that permeation of moisture and oxygen can be effectively suppressed.

In addition, the entire thickness of the moisture absorbing layer 220, the organic barrier layer 230, and the inorganic barrier layer 240 is formed to be included within a range of 10 nm to 10,000 nm.

As the thickness of the inorganic barrier layer 240 is increased, the entire breathability of the thin film encapsulation layer 210 is significantly decreased. However, when the inorganic barrier layer is too thick, a temperature increase may occur during the deposition process so that the OLED display 100 may be damage and the entire thickness of the OLED display 100 may be increased more than necessary. When the inorganic barrier layer 240 is too thin, permeation of moisture and oxygen cannot be effectively suppressed. In consideration of these characteristics, it is preferred that the entire thickness of the inorganic barrier layer 24 is included in a range of less than 10 μm.

Hereinafter, the effect that the thin film encapsulation layer 210 of the OLED display 100 according to the exemplary embodiment of the present invention prevents permeation of moisture or oxygen will be described in further detail.

The inorganic barrier layer 240 having a highly condensed thin film primarily suppresses permeation of moisture or oxygen. The moisture and oxygen are mostly blocked by the inorganic barrier layer 240.

A minimum amount of moisture and oxygen passed through the inorganic barrier layer 240 is secondarily blocked by the organic barrier layer 230. The moisture blocking effect of the organic barrier layer 230 is relatively less than that of the inorganic barrier layer 240. However, the organic barrier layer 230 not only suppresses moisture permeation but also performs as a buffer layer that reduces stress between the respective layers due to twist of the OLED display 100 between the moisture absorbing layer 220 and the inorganic barrier layer 240. That is, when the inorganic barrier layer 240 is formed above the moisture absorbing layer without having the organic barrier layer 230 therebetween, stress occurs between the moisture absorbing layer 240 and the inorganic barrier layer 240 due to twist of the OLED display 100 and the stress causes damage to the moisture absorbing layer 220 or the inorganic barrier layer 240, thereby deteriorating the moisture blocking function of the thin film encapsulation layer 210. As described, since the organic barrier layer 230 suppresses the moisture permeation and performs as the buffer layer, the thin film encapsulation layer 210 can be stably prevent permeation of moisture or oxygen.

A minimum amount of moisture or oxygen passed the organic barrier layer 230 is blocked by the moisture absorbing layer 220. In addition, the moisture absorbing layer 220 has low moisture permeability so that permeation of moisture or oxygen can be blocked. However, components that are additionally used as the moisture absorbing layer 220 combine with the moisture or oxygen and suppress permeation of the moisture or oxygen into the OLED. That is, silicon monoxide (SiO), calcium monoxide (CaO), and barium monoxide (BaO) used as the material of the moisture absorbing layer 220 strongly tend to become dioxides through combination with oxygen atoms, and therefore the moisture absorbing layer 220 is combined with the moisture or oxygen that has passed through the organic barrier layer 23 so that permeation of the moisture or oxygen into the OLED 70 can be effectively blocked.

With the above-described configuration, the thin film encapsulation layer 210 of the OLED display 100 according to the exemplary embodiment of the present invention has a water vapor transmission rate (WWTR) of less then 10⁻⁶ g/m²/day.

Therefore, the OLED display 100 can stably and efficiently suppress permeation of moisture or oxygen to the organic emission layer 720 (shown in FIG. 3) and can simultaneously allow the overall thickness of the OLED display 100 to be slim.

In addition, since the moisture absorbing layer 220 is relatively softer than the inorganic barrier layer 240, it also eases stress or impact transmitted to the OLED 70.

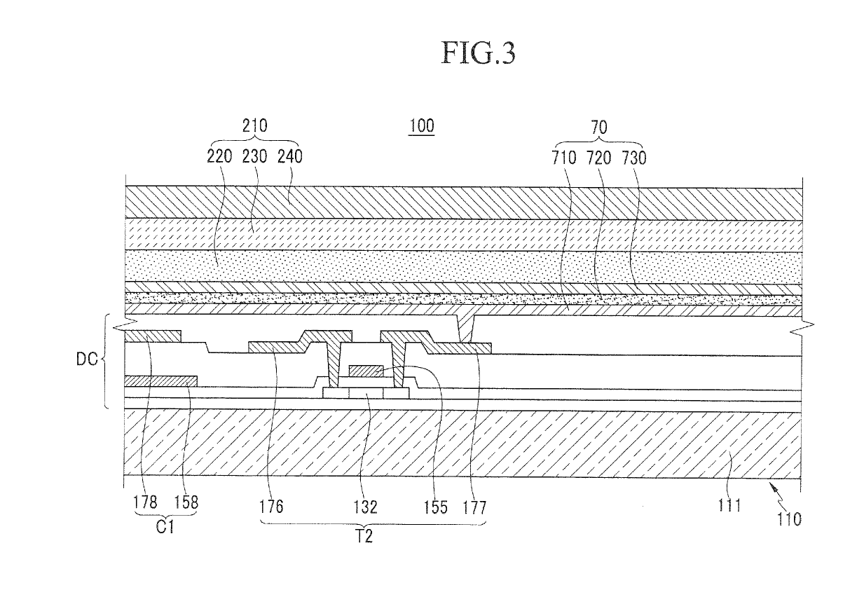

Hereinafter, an internal structure of the OLED display will be described in further detail with reference to FIG. 2 and FIG. 3.

As shown in FIG. 2 and FIG. 3, the OLED 70 includes a first electrode 710, an organic emission layer 720, and a second electrode 730. The driving circuit unit DC includes at least two thin film transistors (TFTs) T1 and T2 and at least one storage capacitor C1. The TFT basically includes a switching transistor T1 and a driving transistor T2.

The storage capacitor C1 may be formed of a first capacitor plate 158 formed on the same layer where the gate electrode 155 is formed, and a second capacitor plate 178 formed on the same layer where the source electrode 176 and the drain electrode 177 are formed. However, the exemplary embodiment of the present invention is not limited thereto. Therefore, one of the capacitor plates 158 and 178 may be formed on the same layer where the semiconductor layer 132 is formed, and the structure of the storage capacitor C1 may variously modified within a range that can be easily realized by a person skilled in the art.

In addition, in FIG. 2 and FIG. 3, the OLED display 100 is illustrated as an active matrix (AM)-type OLED display in a 2Tr-1Cap structure in which two TFTs T1 and T2 and one storage capacitor C1 are formed in one pixel, but the exemplary embodiment of the present invention is not limited thereto. Therefore, the OLED display 100 can have various structures. For example, three or more TFTs and two or more capacitors can be provided in one pixel of the OLED display 100, and separate wires can be further provided in the OLED display 100. Here, a pixel is a minimum unit for displaying an image, and the OLED display 100 displays an image by using a plurality of pixels.

In addition, in FIG. 2, reference numeral SL1 denotes a scan line, and reference numeral DL1 denotes a data line. Reference numeral VDD denotes a power source line, and reference numeral O_{LED} denotes an output current.

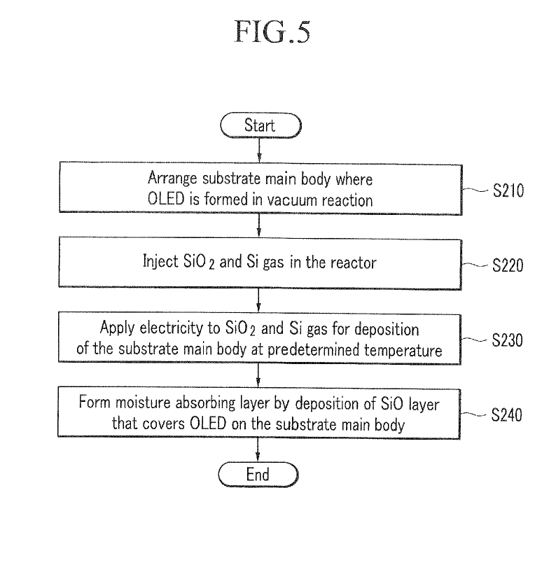

Hereinafter, referring to FIG. 1, FIG. 4, and FIG. 5, a manufacturing method of the OLED display 100 according to the exemplary embodiment of the present invention will be described, focusing on a process for forming the thin film encapsulation layer 210.

As shown in FIG. 1 and FIG. 4, the OLED 70 is first formed on the substrate main body 111 (S100). Next, the moisture absorbing layer 220 covering the OLD 70 is formed on the substrate main body 111 through a thermal evaporation process (S200). In this case, a vacuum evaporation method is used as the thermal evaporation process. In addition, the moisture absorbing layer 220 is made of one of silicon monoxide (SiO), calcium monoxide (CaO), and barium monoxide (BaO).

Referring to FIG. 5, the process for forming the moisture absorbing layer 220 will be described in further detail. In the following description, the moisture absorbing layer 220 is made of, for example, silicon monoxide (SiO).

The substrate main body 111 where the OLED 70 is formed is disposed on a vacuum reactor (S210). Silicon dioxide (SiO₂) and silicon (Si) gas are injected into the reactor (S220), and electricity is applied to the silicon dioxide (SiO₂) and silicon (Si) gas to start deposition of the substrate main body 111 at a predetermined temperature (S230). Here, the predetermined temperature is included within a range that does not damage the OLED 70. The silicon dioxide and silicon gas react with each other so that silicon monoxide SiO is formed, and the silicon monoxide SiO is deposited on the substrate main body 111 so that the moisture absorbing layer 220 covering the OLED 70 is formed (S240). For example, in this case, the deposition speed is 3 Å/sec, and the reactor is evacuated to a degree of vacuum of about 10⁻⁷torr.

Referring to FIG. 4, the organic barrier layer 230 that covers the moisture absorbing layer 220 is formed on the substrate main body 111 through the thermal evaporation process (S300). The organic barrier layer 230 is made of a polymer-based material. Hereinafter, the organic barrier layer 230 will be described to be made of, for example, polyimide.

The polyimide is deposited on the substrate main body 111 through the thermal evaporation process to thereby form the organic barrier layer 230. In this case, the thermal evaporation process is performed at a temperature range that does not damage the OLED 70. As described, the moisture absorbing layer 220 and the organic barrier layer 230 are consecutively formed through the thermal evaporation process, and therefore the entire manufacturing process of the thin film encapsulation layer 210 can be eased and damage to the OLED 70 can be minimized.

In addition, moisture may be generated during deposition of the polyimide through the thermal evaporation process, and permeation of the moisture into the OLED 70 is blocked the moisture absorbing layer 220. The entire thickness of the moisture absorbing layer 220 and the organic barrier layer 230 that are consecutively formed through the thermal evaporation processes is included within a range of 1 nm to 1000 nm, and preferred to be included within a range of 300 nm to 500 nm.

Next, the inorganic barrier layer 240 that covers the organic barrier layer 230 is formed on the substrate main body 111 through the ALD method (S400). The inorganic barrier layer 240 is made of a material that includes at least one of Al₂O₃, TiO₂, ZrO, SiO₂, AlON, AlN, SiON, Si₃N₄, ZnO, and Ta₂O₅. In addition, when forming the inorganic barrier layer 240 through the ADL process, the inorganic insulating material is grown at a temperature below 100 degrees Celsius to prevent damage to the OLED 70.

The entire thickness of the moisture absorbing layer 220, the organic barrier layer 230, and the inorganic barrier layer 240 has a thickness of a range between 10 nm to 10,000 nm.

The thin film encapsulation layer 210 that can stably and effectively suppress permeation of moisture or oxygen into the organic emission layer 720 can be easily and efficiently formed through the above-described manufacturing method.

In addition, the entire thickness of the OLED display 100 can be relatively slim.

According to the present invention, the OLED display can effectively suppress permeation of moisture of oxygen into the organic emission layer through the thin film encapsulation layer and can simultaneously allow the entire thickness of the OLED display to be slim.

In addition, the present invention provides a manufacturing method of the OLED display that can simply and efficiently form a thin film encapsulation layer.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode (OLED) display comprising:
a substrate main body;
an OLED formed on the substrate main body;
a moisture absorbing layer formed on the substrate main body and covering the OLED;
an organic barrier layer formed on the substrate main body and covering the moisture absorbing layer; and
an inorganic barrier layer formed on the substrate main body and covering the organic barrier layer.

2. The OLED display of claim 1, wherein the moisture absorbing layer is formed of a material that is made of at least one of silicon monoxide (SiO), calcium monoxide (CaO), and barium monoxide (BaO).

3. The OLED display of claim 1, wherein the organic barrier layer is made of a polymer-based material.

4. The OLED display of claim 1, wherein the moisture absorbing layer and the organic barrier layer are consecutively formed through thermal evaporation processes.

5. The OLED display of claim 4, wherein at least one of the thermal evaporation processes includes a vacuum evaporation method.

6. The OLED display of claim 4, wherein the entire thickness of the moisture absorbing layer and the organic barrier layer is included within a range of 1 nm to 1000 nm.

7. The OLED display of claim 4, wherein the moisture absorbing layer prevents permeation of moisture generated during the process of forming the organic barrier layer into the organic emission layer.

8. The OLED display of claim 1, wherein the inorganic barrier layer is made of a material that includes at least one of Al₂O₃, TiO₂, ZrO, SiO₂, AlON, AlN, SiON, Si₃N₄, ZnO and Ta₂O₅.

9. The OLED display of claim 8, wherein the inorganic barrier layer is formed through an atomic layer deposition (ALD) method.

10. The OLED display of claim 1, wherein the entire thickness of the moisture absorbing layer, the organic barrier layer, and the inorganic barrier layer is included within a range of 10 nm to 10,000 nm.

11. A manufacturing method of an organic light emitting diode (OLED) display, comprising;
forming an OLED on a substrate main body;
forming a moisture absorbing layer that covers the OLED through a thermal evaporation process;
forming an organic barrier layer that covers the moisture absorbing layer through the thermal evaporation process; and
forming an inorganic barrier layer that covers the organic barrier layer through an atomic layer deposition (ALD) method.

12. The manufacturing method of claim 11, wherein the moisture absorbing layer is formed of a material including at least one of silicon monoxide (SiO), calcium monoxide (CaO), and barium monoxide (BaO).

13. The manufacturing method of claim 11, wherein the organic barrier layer is made of a polymer-based material.

14. The manufacturing method of claim 11, wherein at least one of the thermal evaporation processes includes a vacuum evaporation method.

15. The manufacturing method of claim 14, wherein the moisture absorbing layer is made by deposition of silicon monoxide that is formed from reaction of silicon dioxide (SiO₂) and silicon gas.

16. The manufacturing method of claim 11, wherein the moisture absorbing layer and the organic barrier layer are consecutively formed through the thermal evaporation processes.

17. The manufacturing method of claim 16, wherein the moisture absorbing layer prevents permeation of moisture generated during the process for forming the organic barrier layer into an organic emission layer.

18. The manufacturing method of claim 11, wherein the entire thickness of the moisture absorbing layer and the organic barrier layer is formed to be included within a range of 1 nm to 1000 nm.

19. The manufacturing method of claim 11, wherein the inorganic barrier layer is made of a material that includes at least one of Al₂O₃, TiO₂, ZrO, SiO₂, AlON, AlN, SiON, Si₃N₄, ZnO and Ta₂O₅.

20. The manufacturing method of claim 11, wherein the entire thickness of the moisture absorbing layer, the organic barrier layer, and the inorganic barrier layer is formed to be included within a range of 10 nm to 10,000 nm.
